(19) United States
(12) Patent Application Publication
(10) Pub. No.: US 2002/0020494 A1
(43) Pub. Date: Feb. 21, 2002

(54) PLASMA PROCESSING SYSTEM AND METHOD

(76) Inventors: KEN?apos;ETSU YOKOGAWA, TSURUGASHIMA-SHI (JP); MASARU IZAWA, HINO-SHI (JP); NAOSHI ITABASHI, HACHIOJI-SHI (JP); NOBUYUKI NEGISHI, KOKUBUNJI-SHI (JP); SHINICHI TACHI, SAYAMA-SHI (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/336,687

(22) Filed: Jun. 21, 1999

(30) Foreign Application Priority Data
Jun. 24, 1998 (JP) 10-176926
Sep. 3, 1998 (JP) 10-249307
Mar. 12, 1999 (JP) 11-066018

(51) Int. Cl. C23F 1/02; H01L 21/302

(52) U.S. Cl. 156/345; 438/723

(57) ABSTRACT

A plasma processing system includes a vacuum chamber having a gas introducing unit, and an electromagnetic wave introducing planar plate and electromagnets disposed in the chamber. A distance between the planar plate and a sample is equal to or less than one half of the smaller one of the diameters of the planar plate and the sample. An electromagnetic wave with a frequency ranging from 300 MHz to 500 MHz and an electromagnetic wave with a frequency ranging from 50 kHz to 30 MHz are superposed to the planar plate. Reaction between the resultant electromagnetic wave superposed and a magnetic field of the electromagnets generates plasma to achieve plasma processing of the sample.

### BACKGROUND OF THE INVENTION

The present invention relates to micro-machining of semiconductor devices, and in particular, to a plasma processing system and a plasma processing method in which semiconductor materials are etched into a contour patterned by lithography.

A plasma processing system conventionally employed to fabricate semiconductor devices, for example, a plasma etching system has been described in pages 55 to 58 of “Hitachi Hyouron”, Vol. 76, No. 7 published in 1994. This is a magneto-micro wave plasma etching system in which electromagnetic waves in a micro-ware range are introduced via a magnetic field generated by a solenoid coil and a microwave circuit into a vacuum chamber filled with gas to produce plasma in the chamber. Since this system produces the plasma with a high plasma density at a low gas pressure, the machining of samples can be conducted at a high speed with high precision. Additionally, a magneto-micro wave plasma etching system using local magnetic fields produced by permanent magnets has been described in pages 1469 to 1471 of “Appl. Phys. Lett.” Vol. 62, No. 13 published in 1993. Since the magnetic fields are generated by permanent magnets, the production cost and power consumption are considerably reduced in comparison with the conventional system. JPA-3-122294 describes a technology in which plasma is generated by high-frequency waves in a range from 100 megaherz (MHz) to one gigaherz (GHz) to efficiently etch samples by use of a magnetic mirror (mirror magnetic field). JP-A-6-224155 describes a technology in which high-frequency waves in a range from 100 MHz to 500 MHz are emitted from a comb-shaped antenna to produce uniform plasma in a chamber having a large diameter.

Particularly to machine silicon-oxide films, systems of narrow gap parallel planar plate type (to be abbreviated as narrow plate type herebelow) have been put to practices. In a system of this type, a high frequency in a range from ten-odd megaherz to several tens of megaherz is applied across a gap of about 1.5 centimeters (cm) to about 3 cm between parallel plates to thereby produce a plasma. In the plasma production, a material source gas is at several tens of mTorr. The system of narrow plate type has a feature that the oxide film etching characteristic is relatively stable for a long period of time.

JP-A-7-307200 describes a technology using a high frequency wave of about 300 MHz from a radial antenna having length equal to about a quarter of a wavelength introduced thereto.

### SUMMARY OF THE INVENTION

It is therefore an object of the present invention to provide a plasma processing system and a plasma processing method to produce a uniform magneto-micro wave plasma for a wide machining area with low power consumption.

Another object of the present invention is to provide a plasma processing system and a plasma processing method capable of conducting a high-speed machining for finer machining with high selectivity and a high aspect ratio.

Still another object of the present invention is to provide a plasma processing system and a plasma processing method in which radicals of the plasma are controlled with high precision independently of plasma generating conditions to thereby achieve the machining with high surface processing efficiency.

Another object of the present invention is to provide a plasma processing system and a plasma processing method in which composition of radicals is kept unchanged in the plasma for a long period of time to continuously attain stable machining characteristics.

The magneto-micro wave plasma etching system using local magnetic fields of permanent magnets includes a plurality of small permanent magnets and hence the plasma is not sufficiently uniform in a region in which the plasma is primarily generated in the magnetic fields. To overcome this difficulty, samples are placed at a position apart from the plasma generation region, namely, the plasma used for the machining is uniformed by diffusion. In consequence, the plasma density is insufficient at the position of samples and there arises a problem that the machining speed is lowered.

Moreover, the systems of ECR type described in JP-A-3-122294 and JP-A-6-224155, however, electromagnetic waves are emitted from a position facing samples to be introduced to a plasma source of magneto-micro wave plasma and hence only an insulating material can be placed at the position facing samples. In consequence, for example, when a high-frequency bias is to be applied to a sample, an earth electrode necessary for the bias cannot be placed at a desired or ideal position facing the sample. This leads to a problem of non-uniformity of the bias. Radicals in plasma exert essential influence on machining characteristics of samples. The radicals are under the influence of substances of walls of the vacuum chamber. Particularly, the substance of the wall at a position facing the sample and a distance between the wall and the sample conspicuously influence machining characteristics of the sample. In other words, the radicals can be controlled by the substance of the wall and the distance. However, in the conventional systems of ECR type, only an insulating material, i.e., only quartz or aluminum oxide can be installed in practices at the position facing the sample, and hence the radicals cannot be controlled in a desired or ideal state.

In the systems of narrow electrode type, the electrode exists at a position opposing to the sample as distinct from the systems of ECR type. This consequently solves the problem of the earth electrode to bias the sample and the problem that the radicals cannot be controlled by the material facing the sample. However, the gas pressure is relatively high in the narrow electrode type and irons incident to the sample are non-uniform in directivity, which leads to deterioration in the fine micro-machining. Furthermore, since the distance between the electrodes is at most about 30 millimeters (mm), there arises a problem of a large pressure difference between positions in a machining surface of sample when a gas is introduced at a high flow rate. The phenomenon becomes more apparent as the diameter of samples increases, namely, this is an essential problem to be solved for the machining of wafers of the coming generation having a diameter of 300 mm.

Although the comb-shaped antenna of JP-A-6-224155 and the radial antenna of JP-A 7-307200 improve the uniformity of plasma when compared with cases not using such antennas, it is impossible to attain sufficient plasma uniformity.

The present invention removes the problems above.

In accordance with the present invention, there is provided a plasma processing system in which a highly uniform magneto-micro wave plasma is produced with low power consumption even when the sample has a large machining area. The system can conduct finer machining with high selectively and aspect ratio at a high speed. Particularly, radicals of the plasma are controlled with high precision independently of plasma generating conditions and hence the machining is achieved with high surface processing efficiency. Moreover, composition of radicals is kept unchanged in the plasma for a long period of time to continuously obtain stable machining characteristics.

In the configuration of the present invention, a planar plate is placed at a position facing a sample to introduce plasma exciting electromagnetic waves so that second harmonic waves are applied to the plate and the distance between the plate and the sample is set to a value ranging from about 30 mm to about one half of the diameter of the sample. The second harmonic waves have a frequency ranging from 50 kHz to 30 MHz to excite plasma. A ring-shaped member made of a substance such as silicon is arranged in peripheral areas of the sample so that a bias is applied to the ring-shaped member. The configuration further includes a unit or a function to control temperature of the planar plate, the vacuum chamber wall, and the ring-shaped member.

Due to the construction above, a high-density plasma can be generated with a low magnetic field at a low running cost and hence the fine machining can be achieved at a high speed. Furthermore, second harmonic waves are applied to the planar plate and the distance between the plate and the sample is at most one half of the smaller one of the diameters respectively of the sample and the plate. Therefore, radicals can be controlled in the plasma and reaction on a surface of the sample can be controlled with high precision. This makes it possible to provide a plasma processing system having high selectivity and favorable fine machining characteristics. In accordance with the present invention, the bias is continuously applied to most areas to be brought into contact with the plasma and hence the areas are in a state in which the reaction is being accomplished or in which temperature thereof is being controlled. Therefore, the processing state is not changed with lapse of time and the processing performance is stable for a long period of time.

In the plasma processing system, when the planar plate is silicon, carbon, quartz, or silicon carbide and the material source gas is produced by mixing argon gas with fluorocarbon gas such as C₄F₈, there is provided a plasma processing method to machine a silicon oxide file with high precision. Similarly, when the material source gas primarily including chlorine gas, HBr, or mixture thereof, there is provided a plasma processing method to achieve micro-machining of silicon, aluminum, and wolfram.

In the plasma processing system using an electron cyclotron resonance plasma generated by electromagnetic waves of a frequency ranging from 300 MHz to 500 MHz, radicals can be controlled in the plasma independently of the plasma generating conditions. Particularly, when the distance between a sample and a planar plate placed at a position opposing to the sample, a material on the plate, and electromagnetic waves superposed to the plate are controlled in a range described in this text of the present invention, the radicals can be remarkably controlled and the processing conditions and range can be conspicuously developed. It is resultantly possible to provided a plasma processing system which achieves the micro machining with high precision.

### BRIEF DESCRIPTION OF THE DRAWINGS

The objects and features of the present invention will become more apparent from the consideration of the following detailed description taken in conjunction with the accompanying drawings in which:

FIG. 1 is a diagram specifically showing a first embodiment in accordance with the present invention;

FIG. 2 is a diagram specifically showing a second embodiment in accordance with the present invention;

FIG. 3 is a diagram to explain advantage of the embodiment;

FIG. 4 is a graph to explain advantage of the embodiment;

FIG. 5 is a schematic diagram showing a plurality of fine holes fabricated on a surface of a silicon film of FIG. 2; and

FIG. 6 is a diagram showing an example of irradiating electromagnetic waves onto a ring-shaped member.

### DESCRIPTION OF THE EMBODIMENTS

Description will be given of an embodiment in accordance with the present invention.

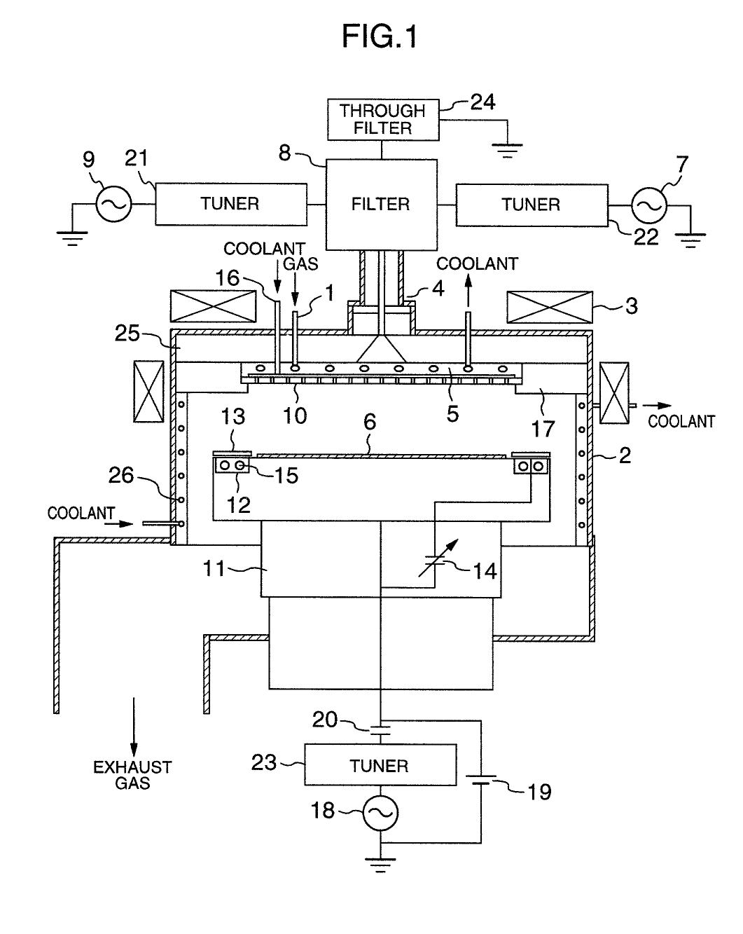

FIG. 1 shows an embodiment of the present invention. This is a basic configuration of a plasma processing system. The configuration includes a vacuum chamber 2 including a gas introducing unit 1. Disposed on chamber 2 is a magnet 3. Gas introduced into chamber 2 is transformed into plasma by interaction between electromagnetic magnetic waves introduced from a coaxial cable 4 onto a planar plate 5 and a magnetic field of magnet 3 to thereby machine a sample 6. Plate 5 to emit electromagnetic waves is equivalent to that described in JP-A-9-321031. Applied to plate 5 are a frequency signal from a plasma generating power source of 450 MHz 7 and a power source of 13.56 MHz 9 via a filter 8. The magnetic field is required, in a plasma generation region between plate 5 and sample 6, to have intensity enough to cause electron cyclotron resonance. Since a 450 MHz magnetic wave is employed in the embodiment of Fig, the intensity is in a range from 100 gauss to 200 gauss. Sample 6 has a diameter of eight inches and the distance between sample 6 and plate 5 is seven centimeters.

In the configuration, plate 5 has a surface made of silicon 10 and material source gas is fed through a plurality of holes fabricated in silicon surface 10 into chamber 2. Disposed on a wall of chamber 2 is a wall temperature controller 26. Controller 26 regulates temperature of the chamber wall in a range from 20° C. to 140° C.

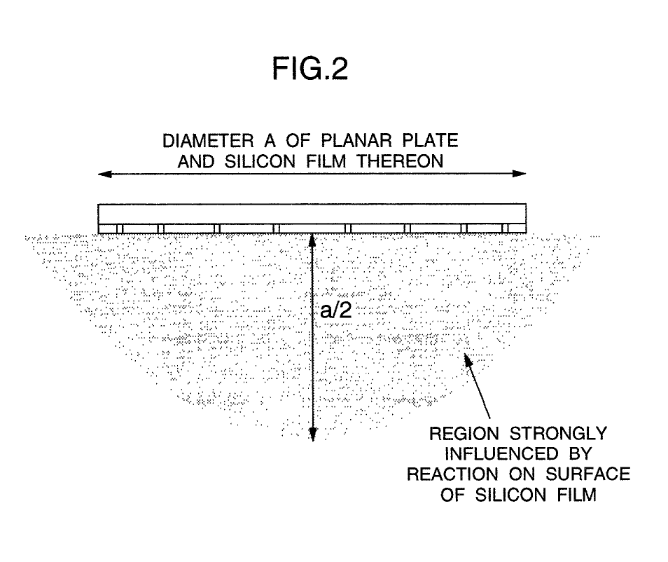

In this embodiment, plate 5 has a diameter of 255 mm. The electromagnetic wave from 13.56 MHz power source 9 functions to adjust electric potential developed between the plasma and the surface of silicon film 10 on plate 5. By adjusting an output from power source 9, the potential on silicon surface 10 can be desirably regulated to thereby control reaction between silicon 10 and radicals in the plasma. In the structure of the present invention, the distance between silicon layer 10 on plate 5 and sample 6 is adjustable in a range from 30 mm to one half of the sample diameter, i.e., 100 mm. The distance is adjusted by moving a sample stand 11 upward or downward. Reaction products of sample 6 or silicon 10 on plate 5 are diffused in vacuum chamber 2. However, in the proximity of surfaces of sample 6 and silicon film 10, the reaction products collide with molecules in the gas phase and float in the space to resultantly form a state of gaseous phase which is under quite a strong influence substantially of the surface reaction. The region of the gaseous phase depends on the size of the area of reaction and develops up to a radius of the circle of reaction area as shown in FIG. 2. Therefore, the reaction can be strongly reflected in both surfaces when the distance between sample 6 and silicon film 10 at a position facing sample 6 is set to a value equal to or less than the radius of sample 6.

For example, when a silicon oxide film is etched using fluorocarbon gas as the material source gas, fluorine radicals as dissociation species of the fluorocarbon gas deteriorate etching characteristics, particularly, etching selectively.

However, in the configuration of the present invention, when fluorine is made to react with silicon 10 and is hence consumed, radicals of fluorine incident to the sample are remarkably reduced. However, when the distance between silicon film 10 and sample 6 is at least the radius of the sample, the reduction in the number of fluorine radicals is lowered and the advantageous effect is abruptly decreased. Minimization of the distance results in the reduction of plasma volume enclosed by silicon film 10 and sample 6. In contrast with an event in which the absolute volume of fluorine radicals generated by the plasma of fluorocarbon gas is proportional to the plasma volume, consumption of fluorine by silicon film 10 depends only on the area of silicon film 10 and a condition of bias applied to silicon film 10. Consequently, while the absolute volume of fluorine radicals produced is lowered by minimizing the distance, the amount of fluorine consumed by silicon film 10 is kept unchanged. Resultantly, the fluorine radicals incident to the sample 6 can be reduced. This is also associated with the reduction of fluorine radicals due to the distance set to at most one half of the sample radius. The radical control function is determined by the distance and 13.56 MHz power superposed to plate 5 and can be controlled independently of plasma generating conditions, for example, the discharge power, the gas pressure, and the gas flow rate. Consequently, the process control range is remarkably expanded.

When the distance between plate 5 and sample 6 is reduced to 30 mm or less, the pressure distribution in the sample surface of the gas fed from the surface of plate 5 becomes worse, which cannot be ignored when the sample diameter increases. This is an essential problem to be solved in the machining of Φ300 wafers of the coming generation. Consequently, favorable characteristics are obtainable when the distance between the plate 5 and the sample 6 is in a range from 30 mm to one half of the wafer diameter (100 mm for Φ200 wafers and 150 mm for Φ150 wafers). In the etching a silicon oxide film, a deep fine hole is required to be fabricated with high etching selectively at a high speed. Characteristics of fine machining and etching selectivity are dominated by active species in the gaseous phase and an incident ion density. Between these factors, there exists a relationship of trade-off. Therefore, the present invention, which makes it possible to control active species with high precision independently of the plasma generating conditions, realizes an advantageous silicon oxide etching characteristic which cannot be obtained by the conventional technology. In addition, a temperature control unit 16 is arranged on plate 5 to minimize variation with respect to time of the surface reaction of silicon film 10.

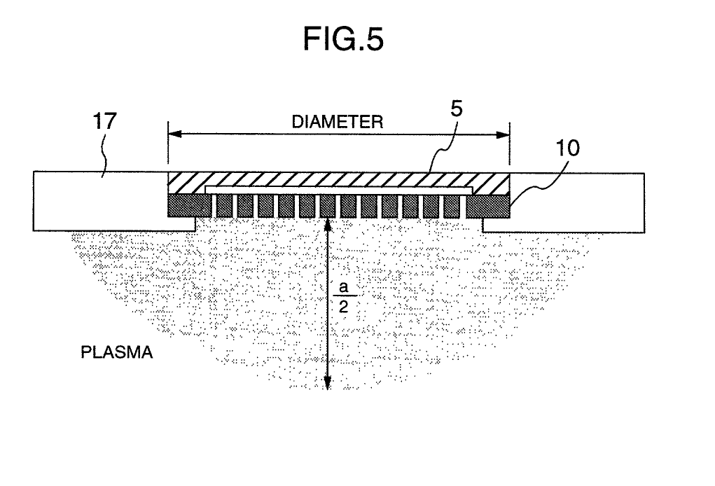

FIGS. 5 shows details of a material source gas introducing section including a plurality of small holes in silicon layer 10 on the surface of plate 5 shown in FIG. 2.

In this embodiment of the present invention, a ring-shaped member 12 shown in FIG. 1 is arranged in the periphery of sample 6. Member 12 has a surface made of silicon 12 which is brought into contact with the plasma. The configuration further includes a capacitor 14 to divide the bias applied to sample 6 to apply resultant bias to silicon film 13. Disposed just below member 12 is a temperature controller 15 to keep temperature of member 12 at a fixed value. A silicon wafer as sample 6 is ordinarily covered with a resist mask. The amount of radicals of the plasma incident to the surface of sample 6 is influenced by reaction with the resist mask. Fluorine radicals derived from the plasma of fluorocarbon gas such as C₄F₈ are consumed through reaction with the resist. The amount of fluorine radicals effectively incident to sample 6 is determined by the reaction. Therefore, as in the description of FIG. 2, the amount of fluorine radicals similarly varies between the central section and the peripheral section of sample 6. Member 12 consumes fluorine radicals remaining in the proximity of sample 6 to uniform the amount of radicals incident to sample 6. The reaction on the surface of member 12 is adjustable by the bias regulated by the bias controller described above. The variation in time of the reaction is minimized by cooling function 15. When the width of member 12 in a horizontal direction associated with the sample surface is set to the distance between plate 5 and sample 6, it is possible to completely uniform the radicals incident to sample 6. However, the width is substantially required only to be 20 mm or more to advantageously uniform the radicals. Resultantly, the width is set to an effective zone ranging from the distance between plate 5 and sample 6 to 20 mm. Height of member 12 in a direction orthogonal to sample 6 is also related to the width. The height can be set to a larger value as the width increases. Substantially, for a given height, an optimal width is set to a value in a range from 0 mm to 40 mm. In the embodiment of FIG. 1, the surface material of member 12 is silicon 13. However, carbon, silicon carbide, quartz, aluminum oxide, or aluminum may be used to obtain an equivalent advantage depending on types of radicals to be controlled.

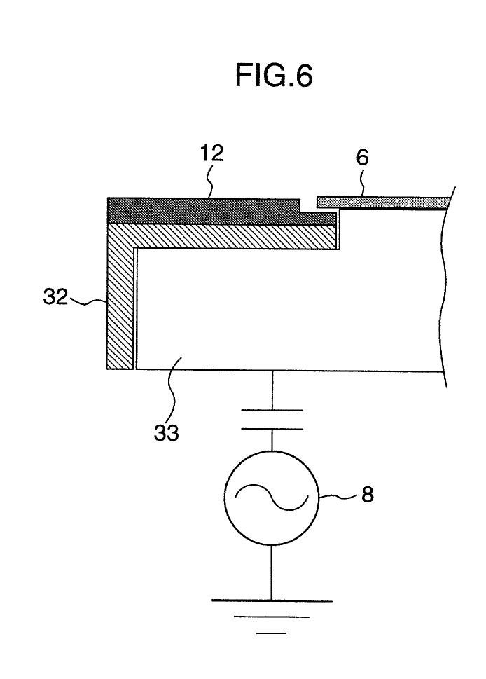

FIG. 6 shows a specific method of feeding an electromagnetic wave onto member 12. From an 800 kHz power supply, which is commonly used for sample 6, electromagnetic waves are fed via a dielectric substance 32 to member 12. Capacity of dielectric 32 is adjustable by changing thickness thereof to thereby control power of the electromagnetic waves supplied to member 12. In addition to dielectric as shown in FIG. 6, there may be employed a variable capacitor to control the power. In accordance with the present invention, most areas which are brought into contact with the plasma are biased or are provided with a temperature control function. Consequently, the internal state of the vacuum chamber is little changed with lapse of time and the processing performance is stable for a long period of time. When the temperature of vacuum chamber 2, plate 5, and member 12 is controlled in a range from 20° C. to 140° C., absorbing radicals can be stabilized and hence the variation with lapse of time of processing characteristics can be minimized.

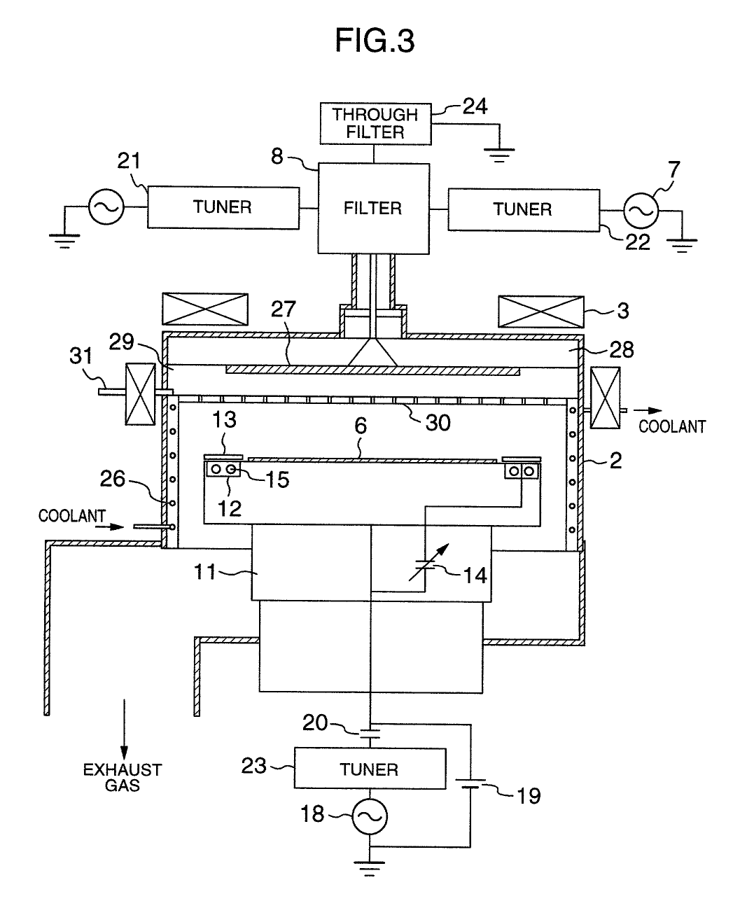

The configuration of FIG. 1 includes a quartz ring 17 to weaken intensity of the electric field in peripheral areas of plate 5 and silicon film 10 to thereby generate uniform plasma. In this embodiment, heat capacity of the 17 is controlled by the volume (thickness) of ring 17 to regulate temperature of ring 17. Although a quartz ring is employed in the embodiment of FIG. 1, there may be used another dielectric such as aluminum oxide, silicon nitride, or a polyimide resin to obtain an equivalent advantage. The quartz ring is arranged only in the circumferential regions of plate 5 and silicon film 10. However, a similar advantage can be attained by disposing quartz on the overall areas. As can be seen from FIG. 3, when a dielectric substance is disposed on an atmosphere side of planar plate 5 to keep vacuum by the dielectric substance, the configuration of the plasma processing system can be simplified. In FIG. 3, only the constituent components different from those of FIG. 1 are assigned with reference numerals. The same components are assigned with the same reference numerals and will not be described. In the embodiment of FIG. 3, the surface reaction of silicon film 10 of the embodiment of FIG. 1 cannot be utilized. However, the other functions are also provided and hence the system configuration is simple and advantageous in applications of micro-machining which requires only a little reaction at the position facing the sample.

Regardless of the system constitution shown in FIGS. 1 and 2, the advantageous control of radicals can be achieved by setting the distance between the sample and the member at a position facing the sample to a value in a range from 30 mm to one half of the sample diameter in accordance with the present invention. The advantage of uniform radicals can also be obtained by arranging the ring-shaped member in the periphery of the sample.

Description will now be given of an example of operation in the first embodiment of FIG. 1. When a silicon oxide film is etched in the embodiment, the material source gas is mixture of argon and C₄F₈ in accordance with the present invention. The gas has a pressure of two pascal (Pa) and the flow rate is 400 sccm for argon and 15 sccm for C₄F₈. To generate plasma, the plate 5 is powered with 800 watt by 450 MHz power supply 7.

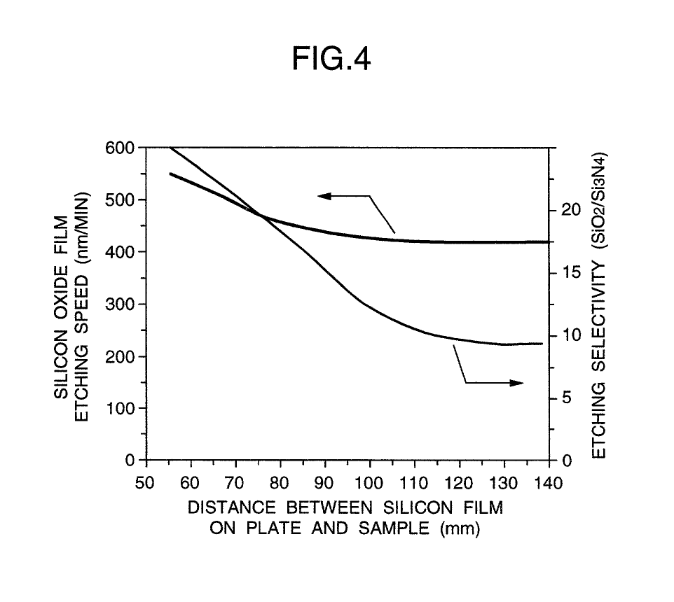

By superposing power of 300 watt from 13.56 MHz power source 9 onto the 450 MHz wave, potential between silicon film 10 on plate 5 and the plasma is adjusted. Sample 6 is a wafer with a diameter of 200 mm. The region of stand 11 which is brought into contact with sample 6 is kept at −20° C. to regulate temperature of sample 6. Electromagnetic waves are fed from power source 18 onto sample 6 to control energy of ions fed from the plasma onto sample 6. FIG. 4 shows in a graph an etching speed of silicon oxide film and etching speed difference (selectivity) between silicon oxide film and silicon nitride film in the example above. The etching characteristic with respect to distance between silicon film 10 and sample 6 has been obtained by changing height of stand 11. To indicate the advantageous distance control of the present invention, the distance between silicon film 10 and sample 6 is set to a value larger than one half of the sample diameter, i.e., 140 mm. As can be seen from the graph of FIG. 4, although the etching steed is not greatly influenced by the distance, the etching selectivity remarkably varies depending on the distance. Particularly, the etching selectively is advantageously improved when compared with the etching selectivity in the distance below one half of the sample diameter, i.e., about 100 mm. This confirms usefulness of the present invention.

Although a frequency of 450 MHz is employed for electromagnetic waves to produce plasma in the embodiment, an equivalent advantage is obtainable with a frequency ranging from 300 MHz to 500 MHz. When the frequency of electromagnetic waves is changed, it is required to alter the intensity of the magnetic field to satisfy a condition of electron cyclotron resonance in the plasma generation region between plate 5 and sample 6. Moreover, a similar advantage can be basically obtained when the frequency is set to a value ranging from 200 MHz to 950 MHz. However, when the value exceeds 500 MHz, the cost of power and the system size are increased in many cases. When the frequency is 300 MHz or less, efficiency of plasma generation is a bit lowered.

The electromagnetic wave superposed to plate 5 has a frequency of 13.56 MHz in the embodiment. However, a frequency ranging from 50 kHz to 30 MHz may be employed to obtain a similar advantage. Moreover, even when the electromagnetic wave to be applied to sample 6 is divided by a capacitor or the like to be superposed to plate 5, there is attained an equivalent advantage. When the superposing electromagnetic wave and that fed to sample 6 are supplied from one power supply, the system can be produced in a simplified configuration at a low cost.

When the frequency is 30 MHz or more, there is developed a low potential between silicone 10 and the plasma. When the frequency is 50 kHz or less, the potential varies depending on a surface state of silicon film 10 on plate 5. Namely, there arises difficulty to apply the present invention under these conditions.

Although silicon film 10 is disposed on plate 5 in the embodiment, carbon, silicon carbide, quartz, aluminum oxide, or aluminum may be employed. Thanks to reaction of the employed substance, the control of radicals can be advantageously achieved in a similar fashion.

Argon and C₄F₈ are used as the source material gas in the embodiment. However, CO gas (50 sccm to 300 sccm), oxygen gas (0.5 sccm to 50 sccm); or CHF₃, CH₂F₂, CH₄, hydrogen, or mixturer thereof (0.5 sccm to 50 sccm) may be added to the source material gas to etch the silicon oxide film. Thanks to the gas added, the processing conditions can be more correctly controlled.

In the etching of the silicon oxide film, an equivalent advantage can also be attained by primarily using either one of the gases: C₂F₆, CHF₃, CF₄, C₃F₆O, C₃F₈, C₂F₄, CF₃I, C₂F₃I, C₃F₆ and C₅F₈. Moreover, CO gas, oxygen gas, or both thereof may be added thereto to achieve a similar advantage.

In the system of the present invention, source material gas primarily including either one of oxygen gas, methane gas, chlorine gas, nitrogen gas, hydrogen, CF₄, C₂F₆, CH₂F₂, C₄F₈, NH₃, NF₃, CH₃OH, C₂H₅OH and SF₆ may be used to etch a semiconductor material substantially made of an organic substance.

In the embodiment, electromagnetic waves are superposed to control reaction on a surface of silicon 10. In addition to the control of reaction by the electromagnetic waves, there may be arranged a temperature control function on the planar plate so that reaction of silicon 10 is regulated by controlling the temperature. This is particularly effective to stabilize reaction on silicon film 10.

In accordance with the embodiment, silicon oxide films are etched. However, a film of silicon or wolfram can be etched by using chlorine gas or gas primarily including chlorine in accordance with the present invention.

In the embodiment, an electromagnetic field applying unit is used to generate plasma, and intensity of the electromagnetic filed is required to be strong enough to cause electron cyclotron resonance. However, an equivalent advantage is obtainable without utilizing such an electromagnetic field or an electromagnetic field satisfying a condition of electron cyclotron resonance, and hence the system can be materialized at a low cost. In either cases, however, the plasma density is lowered to a value which is 0.8 time to 0.3 time that developed in the presence of the electromagnetic field satisfying the condition of electron cyclotron resonance. The application range of the present invention is therefore narrowed in this case.

While the present invention has been described with reference to the particular illustrative embodiments, it is not to be restricted by those embodiments but only by the appended claims. It is to be appreciated that those skilled in the art can change or modify the embodiments without departing from the scope and spirit of the present invention.

1. A plasma processing system for use with a surface processing apparatus in which in a vacuum chamber including vacuum generating means, source material gas supply means, sample setting means, and high-frequency power applying means, the source material gas is transformed into plasma to achieve surface processing of the sample, means for generating the plasma including electromagnetic wave supply means and magnetic field generating means, comprising:
control means for introducing the electromagnetic field from a planar plate disposed in parallel with the sample into the vacuum chamber, for setting distance between the plate and the sample to a value in a range from 30 mm to one half of the smaller one of diameters respectively of the sample or the plate, and for controlling a quantity of reaction between a surface of the planar plate and radicals in the plasma;
means for making radicals incident to a surface of the sample uniform in quantity and type thereof; and
means for reducing variation in time of radicals incident to the sample.

2. A plasma processing system in accordance with claim 1, wherein the planar plate has a diameter ranging from 0.7 time that of the sample to 1.2 times that of the sample.

3. A plasma processing system in accordance with claim 1, wherein the electromagnetic wave to generate plasma has a frequency ranging from 300 MHz to 500 MHz.

4. A plasma processing system in accordance with claim 1, wherein the electromagnetic field generated by the electromagnetic field generating means to generate plasma has intensity satisfying a condition for electron cyclotron resonance between the planar plate and the sample.

5. A plasma processing system in accordance with claim 1, wherein the means for controlling reaction between the surface of the planar plate and the plasma is means for superposing an electromagnetic wave of a second frequency onto the planar plate, the electromagnetic wave being different from the electromagnetic wave of a frequency ranging from 300 MHz 500 MHz.

6. A plasma processing system in accordance with claim 1, wherein the means of controlling reaction between the surface of the planar plate and the plasma is means for controlling temperature of the planar plate.

7. A plasma processing system in accordance with claim 1, wherein the means for controlling reaction between the surface of the planar plate and the plasma is the means of claim 5 for superposing an electromagnetic wave of a second frequency onto the planar plate and the means of claim 6 for controlling temperature of the planar plate.

8. A plasma processing system in accordance with claim 5, wherein:
the second frequency of the electromagnetic wave superposed to the planar plate ranges from 50 kHz to 30 MHz; and
the frequency applied to the planar plate has power of 0.05 W/cm² to 5 W/cm².

9. A plasma processing system in accordance with claim 1, wherein:
the planar plate includes a plurality of holes; and
the source material gas is supplied through the holes.

10. A plasma processing system in accordance with claim 1, wherein the planar plate includes a surface to be brought into contact with the plasma,
the surface being made of silicon, carbon, silicon carbide, quartz, aluminum oxide, or aluminum.

11. A plasma processing system in accordance with claim 6, wherein the means for controlling temperature of the planar plate controls the temperature by circulating a liquid of which temperature is controlled in the planar plate.

12. A plasma processing system in accordance with claim 10, wherein the gas supplying means is arranged at a position in the vacuum chamber,
the position is at an inner position of the vacuum chamber relative to the material surface arranged on the surface of the planar plate to be brought into contact with the plasma.

13. A plasma processing system in accordance with claim 1, wherein the means for making radicals incident to a surface of the sample uniform in quantity and type thereof is a ring-shaped member disposed in a periphery of the sample.

14. A plasma processing system in accordance with claim 13, wherein the ring-shaped member includes a surface to be brought into the plasma,
the surface being made of silicon, carbon, silicon carbide, quartz, aluminum oxide, or aluminum.

15. A plasma processing system in accordance with claim 13, wherein the ring-shaped member is applied with high-frequency power.

16. A plasma processing system in accordance with claim 15, further including a wherein member to apply high-frequency power to the ring-shaped member, wherein
the power applying member is so configured to separate part of the high-frequency power applied to the sample to apply the part to the ring-shaped member.

17. A plasma processing system in accordance with claim 1, wherein means for reducing variation in time of radicals incident to the sample is a wall of the vacuum chamber and the planar plate of claim 1 and the means for control temperature of the ring-shaped member of claim 13.

18. A plasma processing system in accordance with claim 14, wherein the ring-shaped member has a height ranging from 0 mm to 40 mm relative to the sample surface in a direction vertical to the sample surface.

19. A plasma processing system in accordance with claim 14, wherein the ring-shaped member has a width ranging from 20 mm to the distance between the planar plate and the sample in a direction horizontal to the sample surface.

20. A plasma processing system in accordance with claim 16, wherein the member to apply high-frequency power to the ring-shaped member and to separate part of the high-frequency power applied to the sample is a capacitor or has a function of a capacitor.

21. A plasma processing system in accordance with claim 1, wherein the planar plate to supply an electromagnetic wave into the vacuum chamber is coupled via a dielectric substance to a plate at an earth potential,
the electromagnetic wave supplied resonate in transverse magnetic mode (TM) 01 in an dielectric substance enclosed between the planar plate and the earth-potential plate.

22. A plasma processing system in accordance with claim 1, wherein:
the planar plate has a shape of a disk;
the planar plate has a central section connected to a conductor in a shape of a circular cone; and
the planar plate supplies the electromagnetic wave via the conductor.

23. A plasma processing system in accordance with claim 17, wherein:
the means for controlling temperature of the vacuum chamber, the planar plate, and the ring-shaped member controls the temperature by circulating a liquid of which temperature is controlled; and
the temperature controlled ranges from 20 ° C. to 140° C.

24. A plasma processing system in accordance with claim 1, wherein the magnetic field generated by the magnetic field generating means has magnetic lines of force, the lines having a direction vertical to the planar plate and the sample surface of claim 1.

25. A plasma processing system in accordance with claim 1, wherein the magnetic field generated by the magnetic field generating means has magnetic lines of force, the lines having a direction substantially vertical to the planar plate and the sample surface of claim 1.

26. A plasma processing system in accordance with claim 1, wherein all or part of the surface of the planar plate to be brought into contact with the plasma is coated with dielectric.

27. A plasma processing system in accordance with claim 26, wherein the dielectric covering all or part of the surface of the planar plate to be brought into contact with the plasma is quartz, aluminum oxide, silicon nitride, or polyimide resin.

28. A plasma processing system in accordance with claim 26, wherein temperature of the dielectric is controlled to a fixed value in a range from 20° C. to 250° C.

29. A plasma processing system in accordance with claim 1, further including a filter in a power supply path to supply the electromagnetic wave with a frequency ranging from 300 MHz to 500 MHz to the planar plate,
the filter allowing the high-frequency power applied to the sample to flow to the earth.

30. A plasma processing method for use with a plasma processing system in accordance with claim 1, comprising the step of applying the high-frequency power with a frequency ranging from 200 kHz to 14 MHz to the sample with a density of 0.5 W/cm² to 8 W/cm² to achieve surface processing of the sample.

31. A plasma processing system in accordance with claim 15, wherein the high-frequency power is applied to the ring-shaped member with a density of 0 W/cm² to 8 W/cm² in the surface of the member to be brought into contact with the plasma.

32. A plasma processing system in accordance with claim 1, wherein:
a height relative to the sample surface and a width of the magnetic field region associated with the electron cyclotron resonance condition generated between the planar plate and the sample by the magnetic field generating means are controlled; and
radicals generated in the plasma is controlled.

33. A plasma processing system in accordance with claim 1, wherein:
the vacuum chamber includes an upper section made of an insulating material, i.e., quartz or aluminum oxide;
the system further including, on an atmosphere side of the insulating material, a planar plate arranged via dielectric on the earth-potential conductor of claim 20; and
the electromagnetic wave of claim 3 is applied to the planar plate to generate plasma in the vacuum chamber through reaction between the electromagnetic wave and the magnetic field.

34. A plasma processing system for processing a planar sample, wherein a distance between the sample and a member facing the sample ranges from 30 mm to one half of a diameter of the sample.

35. A plasma processing system in accordance with claim 34, wherein the ring-shaped member of claim 15 is arranged in a periphery of the sample.

36. A plasma processing system in accordance with claim 34, wherein the member placed at a position facing the sample is made of quartz, aluminum oxide, silicon, silicon nitride, silicon carbide, or polyimide resin.

37. A plasma processing method for use in a plasma processing system in accordance with claim 1, comprising the steps of:
using a mixture of argon and C₄F₈ as the source material gas; and
etching a silicon oxide film under conditions that argon has a flow rate ranging from 50 sccm to 2000 sccm, C₄F₈ has a flow rate ranging from 0.5 scam to 50 scam, and the mixture has a pressure ranging from 0.01 Pa to 3 Pa.

38. A plasma processing method in accordance with claim 37, further including the step of adding CO gas the mixture to etch a silicon oxide film, the CO gas having a flow rate ranging 50 scam to 300 sccm.

39. A plasma processing method in accordance with claim 37, further including the step of adding oxygen gas to the mixture to etch a silicon oxide film, the oxygen gas having a flow rate ranging 0.5 scam to 50 sccm.

40. A plasma processing method in accordance with claim 37, further including the step of adding CHF₃, CH₂F₂, CH₄, CH₃F hydrogen gas, or a mixture thereof is added to the mixture to etch a silicon oxide film, the gas added having a flow rate ranging 0.5 scam to 50 sccm.

41. A plasma processing method for use with a plasma processing system in accordance with claim 1, further including the step of using C₂F₆, CHF₃, C₃F₆O₅, C₃F₈, or C₅H₈ C₂F₄, CF₃I, C₂F₅I, C₃F₆ gas to etch a silicon oxide film.

42. A plasma processing system, wherein CO gas is added to the gas of claim 41 to etch a silicon oxide film.

43. A plasma processing system, wherein oxygen gas is added to the gas of claim 41 to etch a silicon oxide film.

44. A plasma etching method for use with a plasma processing method for use in the plasma processing system in accordance with claim 1, comprising the step of:
using as the source material gas a mixture of argon and C₅F₈; and
etching a silicon oxide film under conditions that argon has a flow rate ranging from 50 sccm to 2000 sccm, C₅F₈ has a flow rate ranging from 0.5 sccm to 50 sccm, and the mixture has a pressure ranging from 0.01 Pa to 3 Pa.

45. A plasma processing method for use in the plasma processing system in accordance with claim 1, comprising the step of:
using chlorine as the source material gas; and
etching a material of silicon, aluminum, wolfram, or a material primarily including silicon, aluminum, or wolfram under a condition that the gas has a pressure ranging from 0.1 Pa to 4 Pa.

46. A plasma processing method for use in the plasma processing system in accordance with claim 1, comprising the step of:
using HBr as the source material gas; and
etching a material of silicon, aluminum, wolfram, or a material primarily including silicon, aluminum, or wolfram under a condition that the gas has a pressure ranging from 0.1 Pa to 4 Pa.

47. A plasma processing method for use in the plasma processing system in accordance with claim 1, comprising the step of:
using a mixture of chlorine and HBr as the source material gas; and
etching a material of silicon, aluminum, wolfram, or a material primarily including silicon, aluminum, or wolfram under a condition that the mixture has a pressure ranging from 0.1 Pa to 4 Pa.

48. A plasma processing method in accordance with claim 45, further including the step of:
adding oxygen gas to the source material gas to etch a material of silicon, aluminum, wolfram, or a material primarily including silicon, aluminum, or wolfram.

49. A plasma processing system in accordance with claim 1, wherein methane gas, chlorine gas, nitrogen gas, hydrogen, CF₄, C₂F₆, CH₂F₂, C₄F₈, NH₃, NF₃, CH₃OH, C₂H₅OH or SF₆ is used as the source material gas to etch a material primarily including an organic substance.

50. A plasma processing system in accordance with claim 1, wherein the magnetic field generated by the magnetic field generating means is intensity of 100 gauss or less between the planar plate and the sample.

51. A plasma processing system in accordance with claim 1, wherein the plasma is generated without using the magnetic field generating means.

52. A plasma processing system in accordance with claim 1, wherein the second electromagnetic wave superpose to the planar plate in accordance with claim 5 is divided to obtain part thereof to supply the part to the sample in accordance with claim 29.

53. A plasma processing system in accordance with claim 1, wherein the electromagnetic wave to generate the plasma has a frequency ranging from 200 MHz to 950 MHz.

54. A plasma processing method for use in the plasma processing system in accordance with claim 1, comprising the steps of:
using a mixture of Cl₂+BCl₃, Cl₂+BCl₃+CH₄, Cl₂+BCl₃+CH₄+Ar, Cl₂₊BCl₃+CHF₃, Cl₂+BCl₃+CH₂F₂, Cl₂+BCl₃+HCl, Cl₂₊BCl₃+HCl+CH₄+Ar, Cl₂+BCl₃+N₂, Cl₂, +BCl₃+N₂+HCl, Cl₂+BCl₃+CHCl₃; and
etching material of silica, aluminum, wolfram, or a material primarily including silicon, aluminum, or wolfram under a condition that the mixture has a pressure ranging from 0.1 Pa to 4 Pa.
